(19) United States
(12) Patent Application Publication
(10) Pub. No.: US 2026/0040991 A1
(43) Pub. Date: Feb. 5, 2026

(54) SENSOR PACKAGE AND MANUFACTURING METHOD THEREOF

(71) Applicant: OMNIVISION TECHNOLOGIES, INC., Santa Clara, CA (US)

(72) Inventors: Ying Chung, Hsinchu City (TW); En Chi Li, Hsinchu City (TW); Chi Chih Huang, Hsinchu City (TW); Wei Feng Lin, Hsinchu City (TW)

(73) Assignee: OMNIVISION TECHNOLOGIES, INC., Santa Clara, CA (US)

(21) Appl. No.: 18/792,593

(22) Filed: Aug. 2, 2024

(51) Int. Cl. H01L 23/31; H01L 21/48; H01L 21/56; H01L 23/00; H01L 23/10; H01L 23/13; H01L 23/498; H01L 27/146

(52) U.S. Cl. CPC H01L 23/3135; H01L 21/561; H01L 23/10; H01L 23/13; H01L 23/3142; H01L 23/315; H01L 23/49822; H01L 24/97; H10F 39/8057; H01L 21/481; H01L 23/49816; H01L 24/32; H01L 24/48; H01L 24/73; H01L 2224/32225; H01L 2224/48227; H01L 2224/73265; H01L 2224/97; H10F 39/804

(57) ABSTRACT

A sensor package includes a circuit substrate, a sensor die, an electrical connection, a dielectric dam, a cover layer, and an encapsulant. The circuit substrate includes a first side, a second side opposite to the first side, and a cavity recessed from the first side toward the second side. The sensor die is disposed in the cavity and includes a first side, a sensing area on the first side, and a second side opposite to the first side and facing the circuit substrate. The electrical connection electrically connects the first sides of the sensor die and the circuit substrate. The dielectric dam is disposed on the first side of the circuit substrate and outside the cavity, and the dielectric dam partially covers the electrical connection. The encapsulant is disposed on the first side of the circuit substrate and laterally covers the dielectric dam and the cover layer.

### BACKGROUND

### Technical Field

The present disclosure generally relates to a package and a manufacturing method thereof and, more specifically, to an image sensor package and a manufacturing method thereof.

### Description of Related Art

Image sensors utilize an array of pixels to capture an optical image. There are a variety of techniques to package the image sensors. In accordance with a rapid increase in demand for miniaturized sensor packages, implementation of a sensor package having a compact size has been demanded. For example, a sensor package includes a sensor die encapsulated by an encapsulant, a cover glass is disposed over the sensor die for permitting the incident light to be received by the sensor die, and the cover glass is attached to the sensor die through an epoxy dam which encircles a sensing area of the sensor die.

Although the currently used packaging technique is satisfactory, it includes drawbacks. For example, shrinking the width of the epoxy dam to achieve a smaller package size increases the risk of bleeding to the sensing area of the sensor die and also increases a risk of delamination at an interface of the cover glass and the epoxy dam and at an interface of the sensor die and the epoxy dam. In addition, undesirable flare caused by the reflection of the incident light from the corner of the cover glass and from the epoxy dam occurs. Therefore, in light of the above described problems, a need exists for improved sensor package and manufacturing method thereof.

### SUMMARY

In accordance with some embodiments, a sensor package includes a circuit substrate, a sensor die, an electrical connection, a dielectric dam, a cover layer, and an encapsulant. The circuit substrate includes a first side, a second side opposite to the first side, and a cavity recessed from the first side toward the second side. The sensor die is disposed in the cavity and includes a first side, a sensing area on the first side, and a second side opposite to the first side and facing the circuit substrate. The electrical connection electrically connects the first side of the sensor die and the first side of the circuit substrate. The dielectric dam is disposed on the first side of the circuit substrate and outside the cavity, and the dielectric dam partially covers the electrical connection. The encapsulant is disposed on the first side of the circuit substrate and laterally covers the dielectric dam and the cover layer.

In accordance with some embodiments, a manufacturing method of a sensor package includes: disposing a sensor die in a cavity of a circuit substrate, where the circuit substrate includes a first side, a second side opposite to the first side, and the cavity recessed from the first side toward the second side, and the sensor die includes a first side, a sensing area on the first side, and a second side opposite to the first side and facing the circuit substrate; electrically connecting the sensor die and the first side of the circuit substrate through an electrical connection; forming a dielectric dam on the first side of the circuit substrate and outside the cavity to partially cover the electrical connection; disposing a cover layer on the dielectric dam to cover the sensor die; and forming an encapsulant on the first side of the circuit substrate to laterally cover the dielectric dam and the cover layer.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view illustrating a sensor package, in accordance with some embodiments.

FIGS. 2A-2H are schematic cross-sectional views illustrating a sensor package at various steps of fabrication, in accordance with some embodiments.

FIG. 3 is a schematic cross-sectional view illustrating a sensor package, in accordance with some alternative embodiments.

### DESCRIPTION OF THE EMBODIMENTS

Embodiments of a sensor package and a manufacturing method thereof are described herein. In particular, the sensor package includes a sensor die disposed within a cavity of a circuit substrate, a dielectric dam disposed outside the cavity and partially covering electrical connections between the sensor die and the circuit substrate, a cover layer disposed over the sensor die and attached to the circuit substrate through the dielectric dam, and an encapsulant laterally covering the dielectric dam and the cover layer for protection. By placing the sensor die in the cavity of the circuit substrate and configuring the dielectric dam outside the cavity of the circuit substrate, the restriction of the keep-out zone is eliminated and the impact on the sensing area of the sensor die by the undesirable flare is reduced. Therefore, a relatively compact and cost-saving sensor package may be achieved.

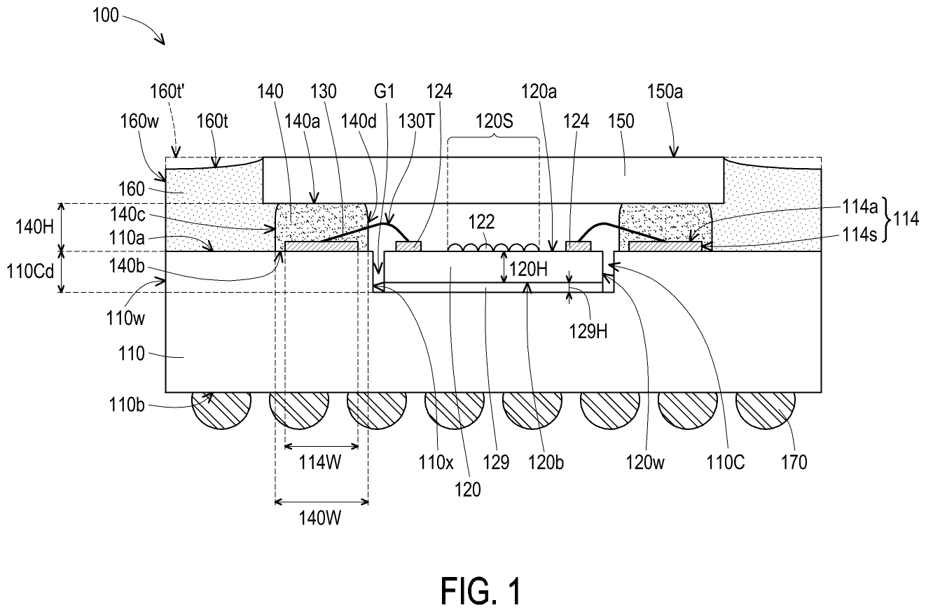

FIG. 1 is a schematic cross-sectional view illustrating a sensor package, in accordance with some embodiments. Referring to FIG. 1, a sensor package 100 includes a circuit substrate 110 having a cavity 110C, a sensor die 120 including a sensing area 120S and disposed inside the cavity 110C of the circuit substrate 110, electrical connections 130 connecting the sensor die 120 and the circuit substrate 110, a dielectric dam 140 disposed on the circuit substrate 110 and partially covering the electrical connections 130, a cover layer 150 disposed over the dielectric dam 140 and covering the sensing area 120S of the sensor die 120, and an encapsulant 160 laterally covering the dielectric dam 140 and the cover layer 150.

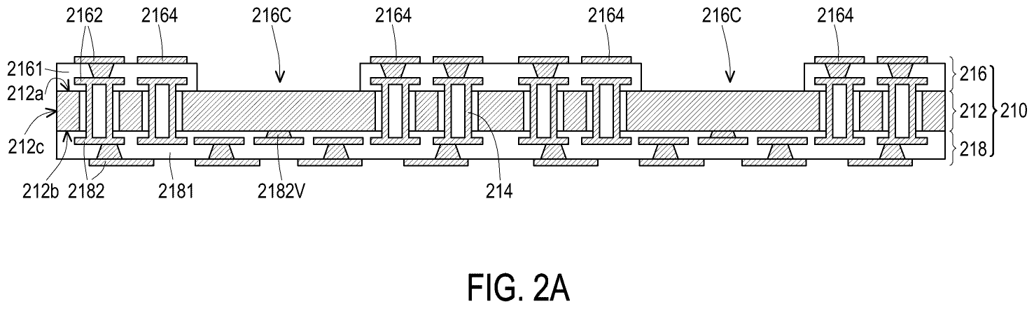

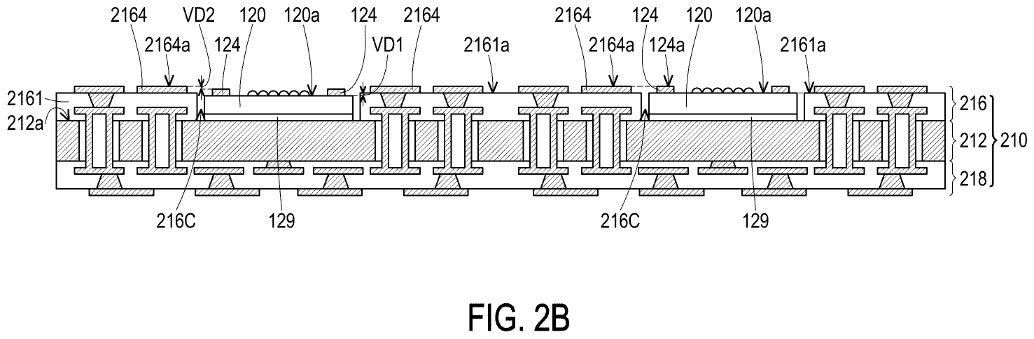

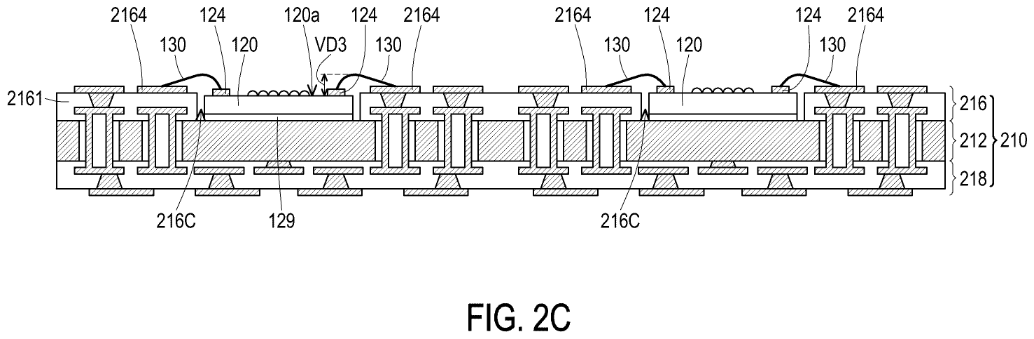

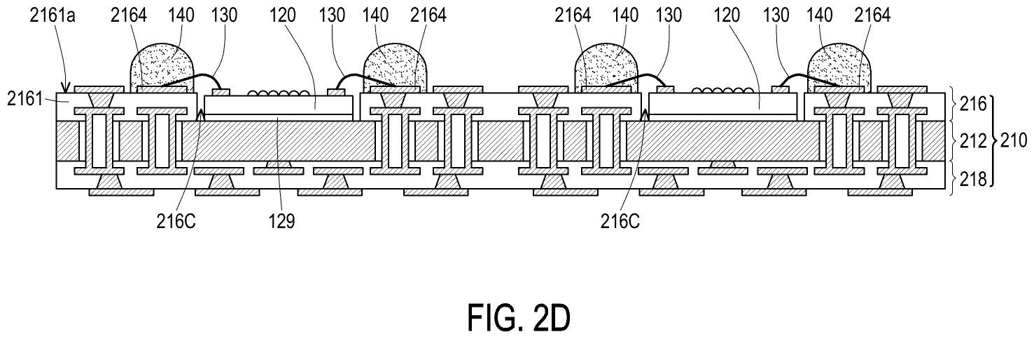

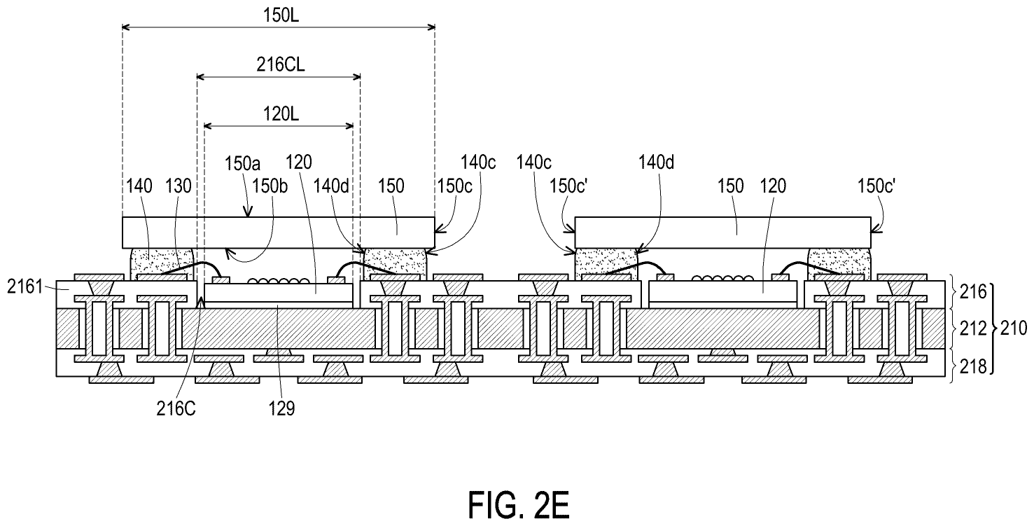

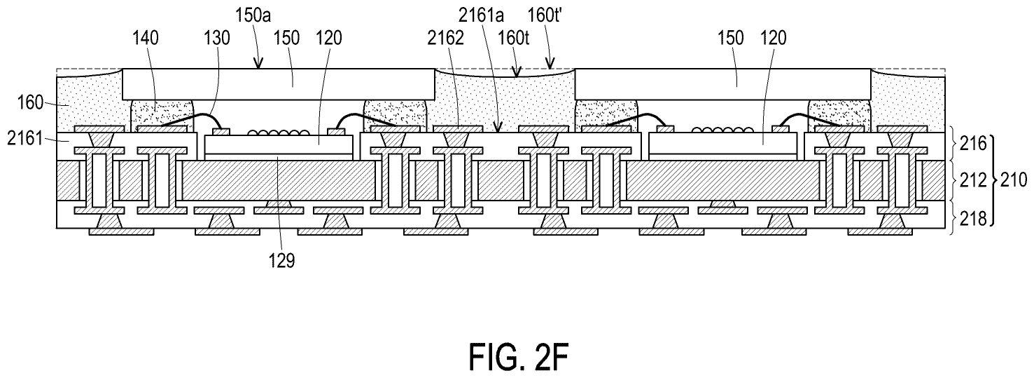

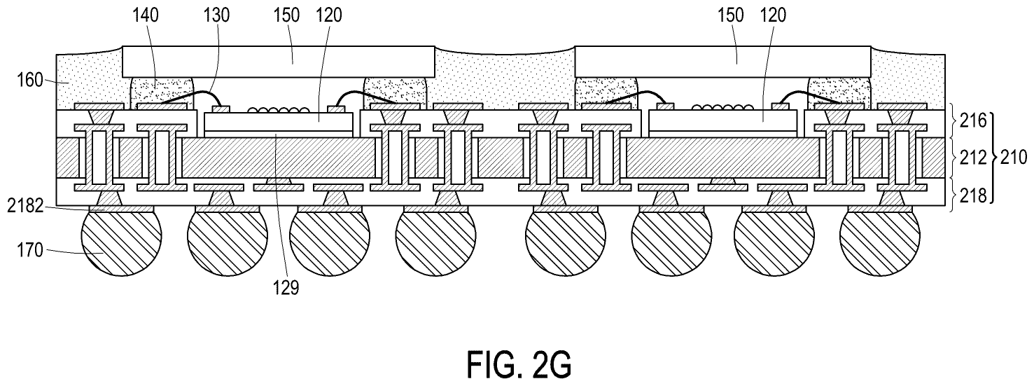

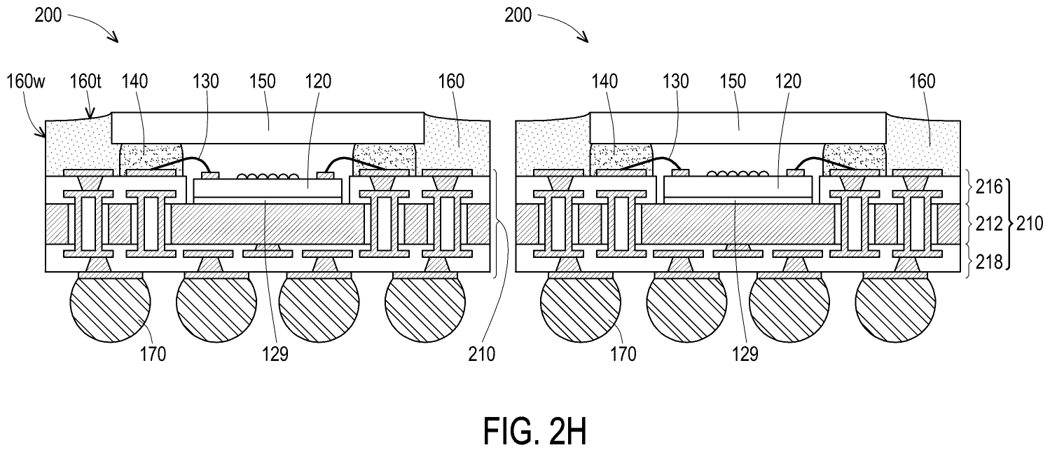

The circuit substrate 110 may include a first side 110a, a second side 110b opposite to the first side 110a, a sidewall 110w connected to the first side 110a and the second side 110b, where the cavity 110C is recessed from the first side 110a toward the second side 110b. The depth of the cavity 110C may vary depending on product design. The circuit substrate 110 may include contact pads 114 disposed at the first side 110a and outside the cavity 110C. The contact pads 114 may be physically and electrically connected to the electrical connections 130. In some embodiments, a plurality of conductive terminals 170 is disposed on the second side 110b of the circuit substrate 110 and electrically connected to the sensor die 120 through the circuit substrate 110 and the electrical connections 130. Note that the details of the circuit substrate 110 are not individually shown, but will be described later in accompanying with FIG. 2A.

With continued reference to FIG. 1, the sensor die 120 may be attached to the circuit substrate 110 through an adhesive layer 129 or any suitable techniques. By accommodating the sensor die 120 in the cavity 110C of the circuit substrate 110, the overall thickness of the sensor package 100 may be reduced. The sensor die 120 may be a complementary metal oxide semiconductor (CMOS) image sensor die; although other types of sensor dies may be used in implementing the disclosure. In some embodiments, the sensor die 120 includes a first side 120a, a second side 120b opposite to the first side 120a, and a sidewall 120w connected to the first side 120a and the second side 120b, where the sensing area 120S is at the first side 120a and the adhesive layer 129 is at the second side 120b.

In some embodiments, the depth 110Cd of the cavity 110C is greater than a combination of the thickness 120H of the sensor die 120 and the thickness 129H of the adhesive layer 129, where the thickness 120H of the sensor die 120 is measured between the first side 120a and the second side 120b. For example, the first side 120a of the sensor die 120 is lower than the first side 110a of the circuit substrate 110, relative to the second side 120b of the circuit substrate 110. In such embodiments, the sensor die 120 is considered to be fully embedded in the cavity 110C of the circuit substrate 110. In alternative embodiments, the first side 120a of the sensor die 120 is substantially leveled (or coplanar) with the first side 110a of the circuit substrate 110. In such embodiments, the sensor die 120 is considered to be partially embedded in the cavity 110C of the circuit substrate 110.

In some embodiments, a gap G1 is between the sidewall 120w and an inner sidewall 110x of the circuit substrate 110 which defines the cavity 110C. For example, the gap G1 is an air-filed gap or a gap filled with an inert gas. The sensing area 120S may include a plurality of pixels 122 arranged in a two-dimensional array, and the sensing area 120S may be referred to as a pixel array region. The sensor die 120 may include the circuitry (not individually shown, e.g., signal generation circuitry, signal processing circuitry, row and column selection circuitry, etc.) associated with sampling and readout of the pixel array. The sensor die 120 may include contact pads 124 disposed at the first side 120a and alongside the sensing area 120S. The contact pads 124 may be physically and electrically connected to the electrical connections 130. For example, the contact pads 124 are electrically coupled to the contact pads 114 of the circuit substrate 110 through the electrical connections 130.

With continued reference to FIG. 1, the electrical connections 130 may be formed between the contact pads 124 of the sensor die 120 and the contact pads 114 of the circuit substrate 110. It should be noted that although the electrical connections 130 are shown as wire bonds, but may have a different form than shown. The dielectric dam 140 may be formed on the first side 110a of the circuit substrate 110 and outside the cavity 110C. In some embodiments, the dielectric dam 140 covers the contact pads 114 and a portion of the electrical connections 130 connected to the contact pads 114. The dielectric dam 140 may include a minimum height 140H measured between a topmost point 140a facing the cover layer 150 and a bottom surface 140b connected to the first side 110a of the circuit substrate 110. The dielectric dam 140 may serve as a support to spatially and vertically separate the topmost points 130T of the electrical connections 130 from the cover layer 150. For example, the topmost point 140a of the dielectric dam 140 is higher than the topmost points 130T of the electrical connections 130, relative to the first side 110a of the circuit substrate 110. Since the sensor die 120 is disposed in the cavity 110C of the circuit substrate 110 and the dielectric dam 140 serves as a support between the circuit substrate 110 and the cover layer 150, the safe clearance of the electrical connections 130 under the cover layer 150 may be provided. Such configuration (e.g., the sensor die 120 disposed in the cavity 110C) may increase the tolerance and process window for the height 140H of the dielectric dam 140.

The dielectric dam 140 may include a maximum width 140W measured between an outer sidewall 140c connected to the encapsulant 160 and an inner sidewall 140d opposite to the outer sidewall 140c. The maximum width 140W of the dielectric dam 140 may depend on the size of the sensor package 100. In some embodiments, the maximum width 140W of the dielectric dam 140 is greater than a maximum width 114W of the respective contact pad 114 covered by the dielectric dam 140. For example, the sidewalls 114s and the top surface 114a of the respective contact pad 114 are covered by the dielectric dam 140. As compared to some cases which include the epoxy dam formed on the sensor die, the dielectric dam 140 formed on the circuit substrate 110 and outside the cavity 110C may provide some advantages. For example, the restriction of the keep-out zone of the sensor die 120 is eliminated and the process window may be enlarged, where the keep-out zone of the sensor die 120 is the region between the sensing area 120S and the sidewall 120w of the sensor die 120. The impact on the sensing area 120S of the sensor die 120 caused by the undesirable flare may be reduced. The size of the sensor die 120 may be reduced and/or the sensing area 120S of the sensor die 120 may be enlarged. A relatively compact and cost-saving sensor package 100 may be achieved.

With continued reference to FIG. 1, the cover layer 150 may be disposed over the dielectric dam 140 to cover the sensor die 120. The cover layer 150 may permit the incident light to reach the sensing area 120S of the sensor die 120. The encapsulant 160 may be disposed on the first side 110a of the circuit substrate 110 and laterally cover the dielectric dam 140 and the cover layer 150. The encapsulant 160 may provide protection against moisture permeation. In some embodiments, the encapsulant 160 is optically opaque to provide the optical isolation of the sensor die 120. The sidewall 110w of the circuit substrate 110 may be substantially coplanar with a sidewall 160w of the encapsulant 160 after the singulation process. In some embodiments, a top surface 160t of the encapsulant 160 has a concave curved profile in the cross-sectional view. In some other embodiments, the encapsulant 160 has a top surface 160t′ which is substantially flat and coplanar with the first side 150a of the cover layer 150. In alternative embodiments, more or fewer elements may be adapted to form the sensor package 100. It should be noted that the configuration of the sensor package 100 in FIG. 1 merely serves as an exemplary illustration and the disclosure is not limited thereto.

FIGS. 2A-2H are schematic cross-sectional views illustrating a sensor package at various steps of fabrication, in accordance with some embodiments. The identical or similar numbers refer to the identical or similar elements throughout the drawings, and detail thereof is not repeated.

Referring to FIG. 2A, a circuit substrate 210 is provided. The circuit substrate 210 may be similar to the circuit substrate 110 described in FIG. 1. For example, the circuit substrate 210 includes a core layer 212, through core vias 214 penetrating through the core layer 212, and a first build-up structure 216 and a second build-up structure 218 disposed at opposing sides of the core layer 212. The core layer 212 may include a first side 212a, a second side 212b opposite to the first side 212a, and a sidewall 212c connected to the first side 212a and the second side 212b. The core layer 212 may be a metallic core (e.g., a copper core), an organic core, an inorganic core, the like, a combination thereof, etc. Using the metallic core as the core layer 212 may provide better heat dissipation for the resulting sensor package. Alternatively, the core layer 212 and the through core vias 214 are omitted, and the circuit substrate 210 may be a coreless substrate. The through core vias 214 may provide electrical paths between the electrical circuits located on the first side 212a and the second side 212b of the core layer 212. In some embodiments, the through core vias 214 are plating through holes, where the hollow region of the respective plating through hole may be empty or may be filled with insulating material(s).

In some embodiments, the first build-up structure 216 disposed on the first side 212a of the core layer 212 includes a cavity 216C exposing a portion of the first side 212a of the core layer 212. In some embodiments where the core layer 212 is a metallic core, the first side 212a of the core layer 212 exposed by the cavity 216C provides a relatively planar/flat surface for carrying the sensor die 120 thereon, since the warpage of the metallic core is relatively low as compared to other type of core materials. The first build-up structure 216 may include one or more dielectric layers 2161 and conductive patterns 2162 formed in/on the dielectric layers 2161 and electrically connected to the through core vias 214. The conductive patterns 2162 may include contact pads 2164 surrounding the respective cavity 216C for further electrical connections. In some embodiments, the second build-up structure 218 disposed on the second side 212b of the core layer 212 includes one or more dielectric layers 2181 and conductive patterns 2182 formed in/on the dielectric layers 2181 and electrically coupled to the conductive patterns 2162 through the through core vias 214. In some embodiments where the core layer 212 is made of a conductive material (e.g., copper), the conductive patterns 2182 include conductive vias 2182V directly connected to the second side 212b of the core layer 212. Alternatively, the conductive vias 2182V are omitted. In some embodiments where the core layer 212 is made of a conductive material (e.g., copper), the sidewall 212c of the core layer 212 is a conductive sidewall exposed by the dielectric layers (2161 and 2181). The sidewall 212c of the core layer 212 may be substantially coplanar with the sidewalls of the dielectric layers (2161 and 2181). The sidewalls of the core layer and the dielectric layers (2161 and 2181) may be collectively viewed as the sidewall of the circuit substrate 210. It should be noted that the configuration of the circuit substrate 210 illustrated herein is an example and may have a different configuration than shown, depending on product requirements.

Referring to FIG. 2B and FIG. 2A, the sensor die 120 may be disposed in the cavity 216C of the circuit substrate 210. In some embodiments, the sensor die 120 is attached to the first side 212a of the core layer 212 through the adhesive layer 129. The sensor die 120 is similar to the sensor die 120 described in FIG. 1, and thus the details of the sensor die 120 are not repeated for the sake of simplicity. It should be noted that although two sensor dies 120 are illustrated, the number of the sensor dies 120 disposed in the cavities 210C of the circuit substrate 210 are not limited in the disclosure. In some embodiments, the first side 120a of the sensor die 120 is lower than the topmost surface 2161a of the dielectric layer 2161 of the first build-up structure 216, where a vertical distance VD1 between the first side 120a and the topmost surface 2161a is non-zero. In some embodiments, the top surface 124a of the respective contact pad 124 of the sensor die 120 is lower than the topmost surface 2164a of the contact pads 2164 of the first build-up structure 216, where a vertical distance VD2 between the top surface 124a and the topmost surface 2164a is non-zero.

In some embodiments, the first side 120a of the sensor die 120 is substantially coplanar with the topmost surface 2161a of the dielectric layer 2161 of the first build-up structure 216. In some embodiments, the top surface 124a of the respective contact pad 124 of the sensor die 120 is substantially coplanar with the topmost surface 2164a of the contact pads 2164 of the first build-up structure 216. It should be noted that although the configuration of the sensor die 120 on the left hand side of FIG. 2B is different from the configuration of the sensor die 120 on the right hand side of FIG. 2B, the configurations of the sensors dies 120 may be the same according to some embodiments.

Referring to FIG. 2C and FIG. 2B, the electrical connections 130 may be formed between the contact pads 124 of the sensor dies 120 and the contact pads 2164 of the circuit substrate 210. For example, the electrical connections 130 are wire bonds. In some embodiments, the wire bonds are formed from gold wires, but other suitable conductive material(s) may be used to form the electrical connections 130. A reliable wire bond process may require that the wires not be bent too sharply. For example, a portion of the wire bonds may extend above the first side 120a of the sensor die 120 by a vertical distance VD3, where the vertical distance VD3 is non-zero. The vertical distance VD3 may depend on the curvature of the wire bonds and other factors.

Referring to FIG. 2D and FIG. 2C, the dielectric dam 140 may be formed on the first build-up structure 216 and outside the cavities 216C. For example, a dispensing process is performed to dispense a dielectric material on the topmost surface 2161a of the dielectric layer 2161 to cover the contact pads 2164 and a portion of the electrical connections 130 connected to the contact pads 2164. The dielectric material may be organic or inorganic material(s) without fillers, such as an epoxy and/or the like. In some embodiments, the dielectric material includes any suitable material having lower reflection and/or may be formed as a glue type or a photoresist type. The dielectric material may not be transparent (e.g., optically opaque). In some embodiments, the dielectric material is a curable composition. After the dispensing, the dielectric material may be cured to form the dielectric dam 140. In some embodiments, after the curing, the dielectric dam 140 has a rounded convex top surface as shown in FIG. 2D. For example, when the curing process is performed on the dielectric material, a peak temperature is about 130° C. for the duration about 30 minutes. Depending on the selected material, the curing temperature and the duration of the dielectric dam 140 may vary.

Referring to FIG. 2E and FIG. 2D, the cover layer 150 may be disposed on the dielectric dam 140. In some embodiments, the cover layer 150 is a transparent cover such as a glass cover. The cover layer 150 may include any suitable material(s) depending on the optical requirements and the warpage performance (e.g., considering the coefficient of thermal expansion compatibility) of the resulting sensor package. In some embodiments, the dielectric dam 140 provides sufficient adhesion property, and the cover layer 150 is adhered to the dielectric dam 140. The cover layer 150 may include a first side 150a, a second side 150b opposite to the first side 150a and facing the sensor die 120, and a sidewall 150c connected to the first side 150a and the second side 150b. The lateral dimension 150L of the cover layer 150 may be greater than the lateral dimension 120L of the underlying sensor die 120. In some embodiments, the lateral dimension 150L of the cover layer 150 is greater than the lateral dimension 216CL of the underlying cavity 216C.

In some embodiments, the cover layer 150 fully overlaps the region defined by the dielectric dam 140. An orthographic area of the cover layer 150 may overlap and be greater than an orthographic area of a boundary defined by the outer sidewall 140c of the dielectric dam 140. For example, the cover layer 150 has the sidewall 150c which is beyond the outer sidewall 140c of the dielectric dam 140. In some embodiments, the cover layer 150 has the sidewall 150c′ which is substantially aligned and/or coplanar with the outer sidewall 140c of the dielectric dam 140. For example, the orthographic area of the cover layer 150 and the orthographic area of the dielectric dam 140 defined by the outer sidewall 140c substantially coincide. The size (e.g., the lateral dimension) of the cover layer 150 may be selected to mitigate the risk of optical flare occurring at the corner of the cover layer 150.

Referring to FIG. 2F and FIG. 2E, an encapsulant 160 may be formed on the first build-up structure 216 of the circuit substrate 210 to laterally cover the cover layer 150 and the dielectric dam 140. For example, the encapsulant 160 is formed on the topmost surface 2161a of the dielectric layer 2161 and covers the topmost one of the conductive patterns 2162. In some embodiments, the sidewall 150c (or the sidewall 150c′, in some embodiments) is covered by the encapsulant 160 and the first side 150a of the cover layer 150 is exposed by the encapsulant 160. In some embodiments, the top surface 160t of the encapsulant 160 is a curved surface (e.g., a concave curved surface recessed toward the circuit substrate 210). In alternative embodiments, the encapsulant 160 has a substantially flat/planar top surface 160t′ which may be substantially coplanar with the first side 150a of the cover layer 150. The encapsulant 160 may be or include a molding compound (e.g., an epoxy molding compound or other molding compound) and may be formed by any suitable techniques. In some embodiments, the encapsulant 160 includes a curable composition. For example, when the curing process is performed on the encapsulant material, a peak temperature is about 135° C. for the duration about 90 minutes. The encapsulant 160 and the dielectric dam 140 may be formed of different materials. In some embodiments, the curing peak temperature of the encapsulant 160 is higher than the curing peak temperature of the dielectric dam 140. The curing duration of the encapsulant 160 may be longer than the curing duration of the dielectric dam. Depending on the selected material, the curing temperature and the duration of the encapsulant 160 may vary. In addition, depending on the selected material and applied method, the encapsulant 160 may have different top surface (e.g., 160t and 160t′).

Referring to FIG. 2G and FIG. 2F, the conductive terminals 170 may be formed on the second build-up structure 218. For example, the conductive patterns 2182 of the second build-up structure 218 include outermost contact pads and the conductive terminals 170 are formed on the outermost contact pads. In some embodiments, the conductive terminals 170 are solder balls formed by reflowing solder materials formed on the outermost contact pads of the conductive patterns 2182. The conductive terminals 170 may include any suitable terminal forms and shapes. In some embodiments where the core layer 212 of the circuit substrate 210 is a metallic core (e.g., a copper core), the lower warpage of the circuit substrate 210 is achieved and the conductive terminals 170 formed on the circuit substrate 210 may have the improved coplanarity.

Referring to FIG. 2H and FIG. 2G, a singulation process may be performed to dice the encapsulant 160 and the circuit substrate 210 to form a plurality of sensor packages 200. After the singulation process, the sidewall 160w of the encapsulant 160 may be substantially coplanar with the sidewalls of the first build-up structure 216, the core layer 212, and the second build-up structure 218. In some embodiments, the top surface 160t of the encapsulant 160 connected to the sidewall 160w may remain curved and be recessed toward the circuit substrate 210. Alternatively, the encapsulant 160 has a substantially flat/planar top surface 160t′ as mentioned in FIG. 2F. The respective sensor package 200 may be similar to the sensor package 100 described in FIG. 1, and thus the details thereof are not repeated for the sake of simplicity.

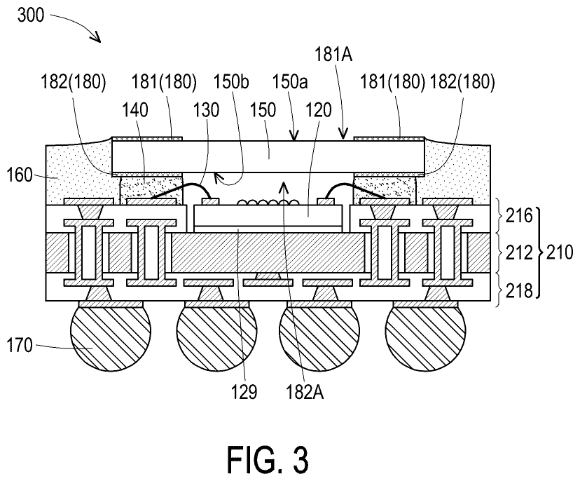

FIG. 3 is a schematic cross-sectional view illustrating a sensor package, in accordance with some alternative embodiments. Like reference numerals refer to corresponding parts throughout the several views of the drawings. Referring to FIG. 3 and FIG. 2H, a sensor package 300 shown in FIG. 3 is similar to the sensor package 200 shown in FIG. 2H, except that the sensor package 300 further includes a light shielding layer 180 disposed on the periphery of the cover layer 150. The light shielding layer 180 may be formed using a variety of optically opaque materials, such as a black photo resist or the like. The light shielding layer 180 may be a single layer or may be a multi-layered structure formed of different materials. The configuration of the light shielding layer 180 may help to reduce the optical flare caused by the reflection of the incident light due to the electrical connections 130 (e.g., the gold wires) or others.

In some embodiments, the light shielding layer 180 includes an upper layer 181 disposed on the first side 150a of the cover layer 150 and along the perimeter of the cover layer 150. The upper layer 181 may include an aperture 181A located on the central region of the cover layer 150 to allow light to pass through. In some embodiments, the light shielding layer 180 includes a lower layer 182 disposed on the second side 150b of the cover layer 150 and between the dielectric dam 140 and the cover layer 150. The lower layer 182 may include an aperture 182A located on the central region of the cover layer 150 to allow light to pass through. The sensor package 300 may include at least one of the upper layer 181 and the lower layer 182. It should be noted that the size, the shape, and the location of the upper layer 181 and the lower layer 182 shown herein are examples and can be adjusted depending on optical and product requirements.

Based on the above, the sensor package includes the dielectric dam landing on the first side of the circuit substrate and outside the cavity in which the sensor die is disposed. In this manner, the restriction of the keep-out zone of the sensor die may be eliminated and the process capability and reliability may be improved. Since the dielectric dam is formed on the circuit substrate instead of the sensor die, the design of the sensor die may be more flexible and the relative compact sensor die may be obtained, thereby reducing the overall thickness of the sensor package. By disposing the dielectric dam of the sensor package on the circuit substrate, the risk of optical flare may be mitigated since the dielectric dam is away from the sensing area of the sensor die as compared to the sensor package having the dielectric dam on the sensor die. The size of the cover layer may be enlarged (e.g., greater than the size of the sensor die), thereby reducing the risk of the optical flare occurring at the corner of the cover layer. In some embodiments where the circuit substrate includes a metallic core layer (e.g., a copper core), the lower warpage and better heat dissipation of the circuit substrate may be obtained, and the sensor die disposed in the cavity of the circuit substrate may be less tilt so that the optical performance of the sensor die may be improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A sensor package, comprising:
a circuit substrate comprising a first side, a second side opposite to the first side, and a cavity recessed from the first side toward the second side;
a sensor die disposed in the cavity and comprising a first side, a sensing area on the first side, and a second side opposite to the first side and facing the circuit substrate;
an electrical connection electrically connecting the first side of the sensor die and the first side of the circuit substrate;
a dielectric dam disposed on the first side of the circuit substrate and outside the cavity, the dielectric dam partially covering the electrical connection;
a cover layer disposed over the dielectric dam and covering the sensor die; and
an encapsulant disposed on the first side of the circuit substrate and laterally covering the dielectric dam and the cover layer.

2. The sensor package of claim 1, wherein the first side of the sensor die is substantially coplanar with the first side of the circuit substrate.

3. The sensor package of claim 1, wherein the first side of the sensor die is lower than the first side of the circuit substrate.

4. The sensor package of claim 1, wherein the cover layer has a lateral dimension greater than a lateral dimension of the sensor die.

5. The sensor package of claim 1, wherein an orthographic area of the cover layer is greater than an orthographic area defined by an outer sidewall of the dielectric dam.

6. The sensor package of claim 1, wherein a sidewall of the cover layer is substantially coplanar with an outer sidewall of the dielectric dam.

7. The sensor package of claim 1, wherein the circuit substrate comprises a contact pad disposed on the first side of the circuit substrate and outside the cavity, the dielectric dam embeds the contact pad therein and covers a portion of the electrical connection connected to the contact pad.

8. The sensor package of claim 1, further comprising:
a light shielding layer disposed on the cover layer and directly over the dielectric dam.

9. The sensor package of claim 1, wherein the circuit substrate comprises a metallic core, and the sensor die is attached to the metallic core.

10. The sensor package of claim 1, wherein the encapsulant comprises a concaved curved top surface and a sidewall connected to the concave curved top surface and substantially coplanar with a sidewall of the circuit substrate.

11. A manufacturing method of a sensor package, comprising:
disposing a sensor die in a cavity of a circuit substrate, wherein:
the circuit substrate comprises a first side, a second side opposite to the first side, and the cavity recessed from the first side toward the second side, and
the sensor die comprises a first side, a sensing area on the first side, and a second side opposite to the first side and facing the circuit substrate;
electrically connecting the first side of the sensor die and the first side of the circuit substrate through an electrical connection;
forming a dielectric dam on the first side of the circuit substrate and outside the cavity to partially cover the electrical connection;
disposing a cover layer over the dielectric dam to cover the sensor die; and
forming an encapsulant on the first side of the circuit substrate to laterally cover the dielectric dam and the cover layer.

12. The manufacturing method of claim 11, further comprising:
performing a singulation process to dice the encapsulant and the circuit substrate, wherein sidewalls of the encapsulant and the circuit substrate are substantially coplanar.

13. The manufacturing method of claim 11, wherein disposing the sensor die in the cavity of the circuit substrate comprises:
attaching the second side of the sensor die to the circuit substrate through an adhesive layer.

14. The manufacturing method of claim 11, wherein electrically connecting the first side of the sensor die and the first side of the circuit substrate through the electrical connection comprises:
performing a wire bonding process to form a wire bond connecting the sensor die and the circuit substrate.

15. The manufacturing method of claim 11, wherein forming the dielectric dam on the first side of the circuit substrate comprises:
performing a dispensing process to form a dielectric material on the first side of the circuit substrate; and
performing a curing process on the dielectric material to form the dielectric dam.

16. The manufacturing method of claim 11, wherein after disposing the cover layer on the dielectric dam, the dielectric dam serves as a support to spatially separate the cover layer and the electrical connection.

17. The manufacturing method of claim 11, wherein forming the encapsulant on the first side of the circuit substrate comprises:
forming an encapsulant material on the first side of the circuit substrate; and
performing a curing process to form the encapsulant.

18. The manufacturing method of claim 11, wherein the dielectric dam and the encapsulant are of different materials, and a curing duration of the encapsulant is longer than that of the dielectric dam.

19. The manufacturing method of claim 11, wherein:
the cover layer is provided with a light shielding layer on a side facing away the sensor die, and
after disposing the cover layer on the dielectric dam, the light shielding layer is directly over the dielectric dam.

20. The manufacturing method of claim 11, wherein:
the cover layer is provided with a light shielding layer on a side facing the sensor die, and
after disposing the cover layer on the dielectric dam, the light shielding layer is between the dielectric dam and the cover layer.
